(19) United States
(12) Patent Application Publication
(10) Pub. No.: US 2021/0084765 A1
(43) Pub. Date: Mar. 18, 2021

(54) Method for Mechanically Connecting and Arranging Electronic Components

(71) Applicant: Robert Bosch GmbH, Stuttgart (DE)

(72) Inventors: Udo Kaess, Walheim (DE); Uwe Liskow, Shanghai (CN); Markus Weiss, Denkendorf (DE)

(21) Appl. No.: 16/477,477

(22) PCT Filed: Dec. 7, 2017
(86) PCT No.: PCT/EP2017/081920

§ 371 Date: Jul. 11, 2019

(30) Foreign Application Priority Data
Jan. 25, 2017 (DE) 10 2017 201 135.1

(51) Int. Cl. H05K 1/14

(52) U.S. Cl. CPC H05K 1/141; H05K 1/144

(57) ABSTRACT

A method for mechanically connecting a first electronic component, in particular a circuit board element, to a second electronic component, in particular a second circuit board element, includes arranging and orienting the first electronic component, which includes a first through-opening in a first direction, above the second electronic component in the first direction in such a way that a second through opening in the first direction or a blind hole in the first direction is arranged at least partially below the first through-opening in the first direction. The method further includes introducing a casting compound into the first through-opening and into the second through-opening or into the first through-opening and into the blind hole, and setting the casting compound in order to fix the first electronic component in relation to the second electronic component.

### FIELD OF THE INVENTION

The invention relates to a method for mechanically connecting a first electronic component, in particular a printed circuit board element, to a second electronic component, in particular a second printed circuit board element, and to an arrangement of electronic components.

### PRIOR ART

Electronic components, for example printed circuit board elements, flex PCBs, direct bonded copper (DBC) elements and/or sensor domes need to be mechanically and electrically connected to one another. Cable connectors, jumpers or the like are often used for the electrical connection. Screws, rivets or the like are often used for the mechanical connection of the two electronic components. The use of screws, rivets or the like leads to mechanical loads of the electronic components during the connecting process. Another disadvantage of the use of screws, rivets or the like for the mechanical connection is that they usually protrude from the electronic component. Under unfavorable circumstances, metal swarf that can generate short circuits may also be formed when using metal screws, rivets or the like. Furthermore, mechanical stresses may be formed when the two electronic components are located at different height levels.

### DISCLOSURE OF THE INVENTION

### Advantages of the Invention

Embodiments of the present invention may advantageously make it possible to connect two electronic components to one another in a way which is technically straightforward and free from mechanical stresses.

According to a first aspect of the invention, a method is provided for mechanically connecting a first electronic component, in particular a printed circuit board element, to a second electronic component, in particular a second printed circuit board element, wherein the first electronic component comprises a first through-opening in a first direction and the second electronic component comprises a second through-opening or a blind hole in the first direction, wherein the method comprises the following steps: arranging and aligning the first electronic component over the second electronic component in the first direction, in such a way that the second through-opening or the blind hole is arranged at least partially below the first through-opening in the first direction; introducing an encapsulation compound into the first through-opening and into the second through-opening, or into the first through-opening and into the blind hole; and curing the encapsulation compound in order to fix the first electronic component in relation to the second electronic component.

One advantage of this is that the two electronic components may typically be connected to one another in a way which is technically straightforward and free from mechanical stresses. Since no screw, rivet or the like is used for the mechanical connection of the two electronic components, no mechanical stresses are generally formed in the electronic components during the mechanical connection.

According to a second aspect of the invention, an arrangement of electronic components is provided, comprising a first electronic component, in particular a first printed circuit board element, and a second electronic component, in particular a second printed circuit board element, characterized in that the first electronic component comprises a first through-opening in a first direction and the second electronic component comprises a second through-opening or a blind hole in the first direction, the second electronic component being arranged below the first electronic component in the first direction in such a way that the second through-opening or the blind hole is arranged at least partially below the first through-opening in the first direction, a monobloc encapsulation compound for connecting the first electronic component to the second electronic component being arranged in the first through-opening and in the second through-opening or the blind hole.

One advantage of this is that the two electronic components may typically be connected to one another in a way which is technically straightforward and free from mechanical stresses. Since no screw, rivet or the like has been used for the mechanical connection of the two electronic components, no mechanical stresses are generally formed in the electronic components during the mechanical connection.

Concepts relating to embodiments of the present invention may, inter alia, be regarded as being based on the ideas and thoughts described below.

According to one embodiment, the first electronic component is arranged above the second electronic component in the first direction, in such a way that—the second through-opening or the blind hole is arranged fully below the first through-opening in the first direction, or—the first through-opening is arranged fully above the second through-opening or the blind hole in the first direction. One advantage of this is that the encapsulation compound generally enters the first through-opening and the second through-opening, or the blind hole, in a particularly straightforward way. As a result, a particularly strong mechanical connection is usually achieved between the two electronic components.

According to one embodiment, the first through-opening and the second through-opening or the blind hole respectively have an elliptical shape, in particular a circular shape, in cross section perpendicularly to the first direction, the first electronic component being aligned with respect to the second electronic component in such a way that the first through-opening is aligned coaxially with the second through-opening or coaxially with the blind hole. One advantage of this is that the encapsulation compound enters the first through-opening and the second through-opening or the blind hole, in a technically particularly straightforward way. In addition, as a result a unique or predetermined position of the two electronic components with respect to one another is generally obtained.

According to one embodiment, the method furthermore comprises the following step: electrically connecting the first electronic component to the second electronic component at a position which is located at most about 0.75 mm, in particular at most about 0.55 mm, away from the first through-opening, the second through-opening and/or the blind hole. One advantage of this is that, even in the event of different thermal expansion coefficients of the two electrical components, essentially no mechanical forces, or only very small mechanical forces, generally act at the position of the electrical connection.

According to one embodiment, the method furthermore comprises the following step: applying a dam material, which extends around the first through-opening, onto a first side of the first electronic component, facing away from the second electronic component; applying a fill material as an encapsulation compound onto that part of the first side of the first electronic component which is enclosed by the dam material, in such a way that the fill material is introduced into the first through-opening and into the second through-opening or into the blind hole. One advantage of this is that the encapsulation material can typically be introduced into the first through-opening and the second through-opening, or the blind hole, in a technically straightforward way. In addition, the encapsulation material may generally cover further elements, for example further electronic components, which are arranged on one of the two electronic components, and insulate these from the environment (for example an oil environment). The dam material may generally be highly viscous or thixotropic, so that the dam material does not run before or during the curing. The fill material may generally have a low viscosity in order to reliably fill cavities and gaps.

According to one embodiment the second through-opening or the blind hole is arranged fully below the first through-opening in the first direction, or the first through-opening is arranged fully above the second through-opening or the blind hole in the first direction. One advantage of this is that the encapsulation compound generally enters the first through-opening and the second through-opening or the blind hole, in a particularly straightforward way. As a result, there is usually a particularly strong mechanical connection between the two electronic components.

According to one embodiment, a part of the encapsulation compound is arranged on a side of the second electronic component facing away from the first electronic component. One advantage of this is that height differences can generally be compensated for in a technically straightforward way by means of the encapsulation compound. In addition, as a result essentially no mechanical stresses are typically formed between the two electronic components. Another advantage of this is that, by means of the encapsulation compound, the two electronic components may generally at the same time be mechanically connected to one another and fastened to a further element (for example a heat sink 70 or a cooling plate). This generally reduces the production outlay.

According to one embodiment, the first through-opening and the second through-opening or the blind hole respectively have an elliptical shape, in particular a circular shape, in cross section perpendicularly to the first direction, the first through-opening being aligned coaxially with the second through-opening or coaxially with the blind hole. One advantage of this is that the encapsulation compound enters the first through-opening and the second through-opening, or the blind hole, in a technically particularly straightforward way. In addition, as a result the two electronic components are generally fixed with respect to one another, or fastened to one another, in a unique or predetermined position.

According to one embodiment, the encapsulation compound is arranged partially between the first electronic component and the second electronic component for surface connection of the first electronic component to the second electronic component. As a result, there is a particularly reliable surface connection between the two electronic components.

The first electronic component and the second electronic component may respectively be, in general, in particular a printed circuit board element or an element which is arranged or fastened on a printed circuit board element.

It is usually also possible to connect more than two (for example three, four or more than four) electronic components, or printed circuit board elements, to one another in the manner described.

It should be pointed out that some of the possible features and advantages of the invention are described herein with reference to different embodiments of the arrangement of electronic components or of the method for mechanical connection. A person skilled in the art will understand that the features may be combined, adapted or substituted in a suitable way in order to achieve further embodiments of the invention.

### BRIEF DESCRIPTION OF THE DRAWINGS

Embodiments of the invention will be described below with reference to the appended drawings, neither the drawings nor the description being intended to be interpreted as restricting the invention.

FIG. 1 shows a cross-sectional view of a first embodiment of the arrangement according to the invention of electronic components;

FIG. 2 shows a cross-sectional view of a second embodiment of the arrangement according to the invention of electronic components;

FIG. 3 shows a cross-sectional view of a third embodiment of the arrangement according to the invention of electronic components; and

FIG. 4 shows a cross-sectional view of a fourth embodiment of the arrangement according to the invention of electronic components.

The figures are merely schematic and not to scale. The same references denote features which are the same or have the same effect in the figures.

### EMBODIMENTS OF THE INVENTION

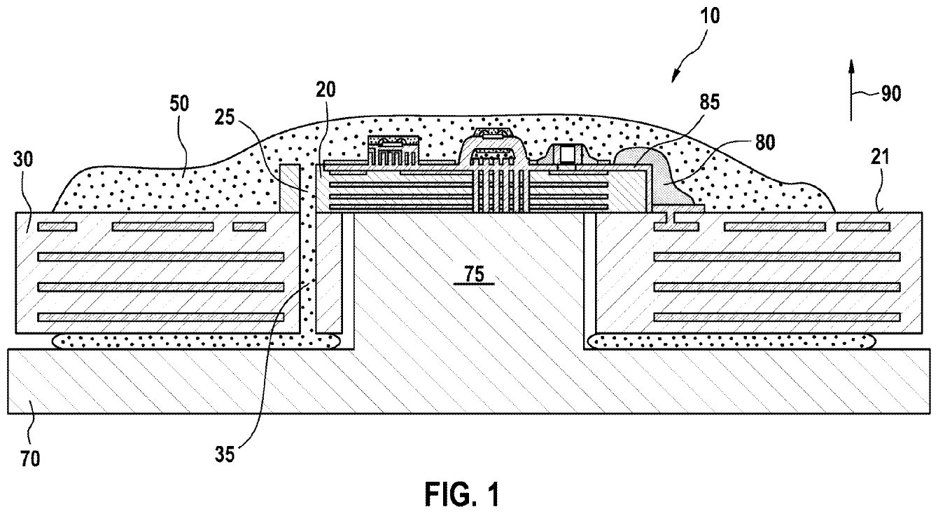

FIG. 1 shows a cross-sectional view of a first embodiment of the arrangement 10 according to the invention of electronic components 20, 30. The arrangement 10 comprises a first electronic component 20, namely a first printed circuit board element, and a second electronic component 30, namely a second printed circuit board element. The first and second printed circuit board elements may respectively be a rigid printed circuit board (PCB), a flexible printed circuit board (PCB), a flex PCB, direct bonded copper (DBC), a flexible printed circuit board (FPC), a sensor or a sensor dome, or the like.

The first printed circuit board is electrically connected by means of two solder positions 80, 81 to the second printed circuit board. It is also conceivable for the two printed circuit board elements to be electrically connected to one another by means of only one solder position, three solder positions or more than three solder positions. The first printed circuit board comprises a first through-opening 25. The first through-opening 25 extends in the first direction 90. The first direction 90 runs from the bottom upwards in FIG. 1. The second printed circuit board comprises a second through-opening 35. The second through-opening 35 likewise extends in the first direction 90. The two through-openings 25, 35 have an equally large cross section perpendicularly to the first direction 90. It is also conceivable for the cross sections to be of different sizes. The cross section perpendicularly to the first direction 90 may be elliptical, in particular circular, rectangular, in particular square. Other cross sections may also be envisioned.

The first printed circuit board element is arranged above the second printed circuit board element in the first direction 90. The first printed circuit board element is arranged on a centrally arranged projection of a heat sink 70 (so-called cooling balcony 75). The second printed circuit board element is located on a part of the encapsulation compound 50, which is in turn partially located on the heat sink 70.

The printed circuit board elements are aligned with respect to one another in such a way that the first through-opening 25 is located above the second through-opening 35. What is essential is that the second through-opening 35 is located at least partially below the first through-opening 25, so that encapsulation compound 50 can pass from the first through-opening 25 along the first direction 90 into the second through-opening 35.

The direction of gravity is usually from the top downward in FIG. 1.

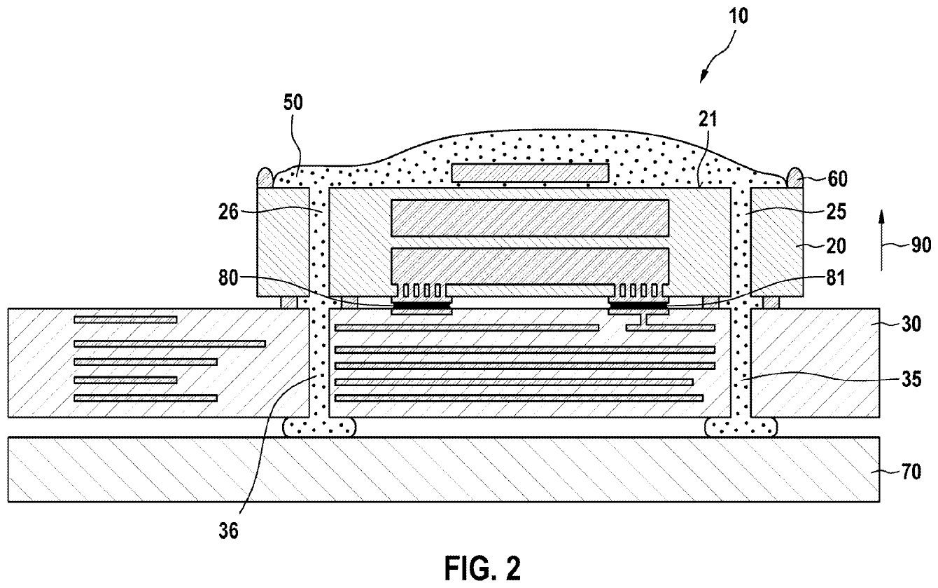

The encapsulation material is applied onto part of a first side 21 of the first printed circuit board element. The first side 21 of the first printed circuit board element faces away from the second printed circuit board element. In FIG. 2, the first side 21 of the first printed circuit board element is the upper side.

The encapsulation material is flowable. The encapsulation material therefore penetrates into the first through-opening 25, or is introduced into it, and consequently into the second through-opening 35. In the embodiment shown in FIG. 1, the encapsulation compound 50 fully covers the first side 21 of the first printed circuit board element. The further elements arranged on the first side 21 of the first printed circuit board element are insulated from the environment by the encapsulation compound 50. The solder position 80 between the outer-lying metallization 85 of the first printed circuit board element and the second printed circuit board element for electrical connection of the two printed circuit board elements is also fully covered by the encapsulation compound 50. The encapsulation compound 50 is likewise partially located between the second printed circuit board element and the heat sink 70. As a result, a height difference between the second printed circuit board element and the heat sink 70 is compensated for. In addition, as a result the second printed circuit board element is fastened on the heat sink 70.

Application-specific printed circuit board element may be selected and combined with one another, for example a locally required printed circuit board with 8 layers, while the main printed circuit board has only 4 layers and is therefore more economical.

Different thicknesses of the printed circuit board elements may also be compensated for by the encapsulation compound 50. For instance, printed circuit board elements usually have a thickness of about 1.6 mm±0.15 mm.

Different heights of the copper tracks may also be compensated for by the encapsulation compound 50. For example, a main printed circuit board may have 35 μm copper tracks and has a high-current printed circuit board adhesively bonded on 105 μm copper tracks. Likewise, gaps between the first printed circuit board element and the second printed circuit board may be filled with the encapsulation compound 50.

The encapsulation compound 50 may be or comprise epoxy resin, polyurethane, acrylate and/or silicone.

After the encapsulation compound 50 has reached into the second through-opening 35 and to further desired positions, the encapsulation compound 50 is cured. This is, for example, carried out by warming or heating.

The first through-opening 25 is aligned flush with the second through-opening 35. It is also conceivable for the first through-opening 25 to have a (small) offset with respect to the second through-opening 35. The first through-opening 25 and the second through-opening 35 are respectively filled fully with encapsulation compound 50.

FIG. 2 shows a cross-sectional view of a second embodiment of the arrangement 10 according to the invention of electronic components 20, 30. In this case, the first electronic component 20, namely the first printed circuit board element, has a smaller width (extending from the left to the right in FIG. 2) than the second electronic component 30, namely the second printed circuit board element. The two printed circuit board elements are connected to one another by means of two first through-openings 25, 26 and two second through-openings 35, 36. The encapsulation compound 50 is present as a continuous encapsulation compound in all the through-openings 25, 26, 35, 36. All the through-openings 25, 26, 35, 36 are filled fully with encapsulation compound 50, or the encapsulation material. The second printed circuit board element does not bear directly, or immediately, on the heat sink 70, but rather a part of the encapsulation compound 50 is located between them.

A layer of dam material 60 extending around the two first through-openings 25, 26, or the two upper openings of the two first through-openings 25, 26, is initially partially applied onto the first side 21 of the first printed circuit board element. The dam material 60 is essentially not flowable and remains at the applied position. Subsequently, a fill material, which is flowable before curing, is applied as an encapsulation material onto that part of the first side 21 of the first printed circuit board element which is enclosed by the dam material 60. The flowable fill material flows into the first through-openings 25, 26 (as an alternative, it may also be applied directly into them) and into the second through-openings 35, 36. Partially, it also flows into the region between the first printed circuit board element and the second printed circuit board element. Likewise, it flows into the region between the second printed circuit board element and the heat sink 70.

Besides the dam material 60 on the first side 21 of the first printed circuit board element, FIG. 2 does not show any flow-limiting devices which prevent the fill material or encapsulation material from spreading or flowing further than as shown in FIG. 2.

Arranged between the two first through-holes or the second through-holes, there are two solder positions 80, for electrical connection of the two printed circuit board elements to one another. The first through-openings 25, 26 are respectively aligned flush with the respective second through-opening 35, 36.

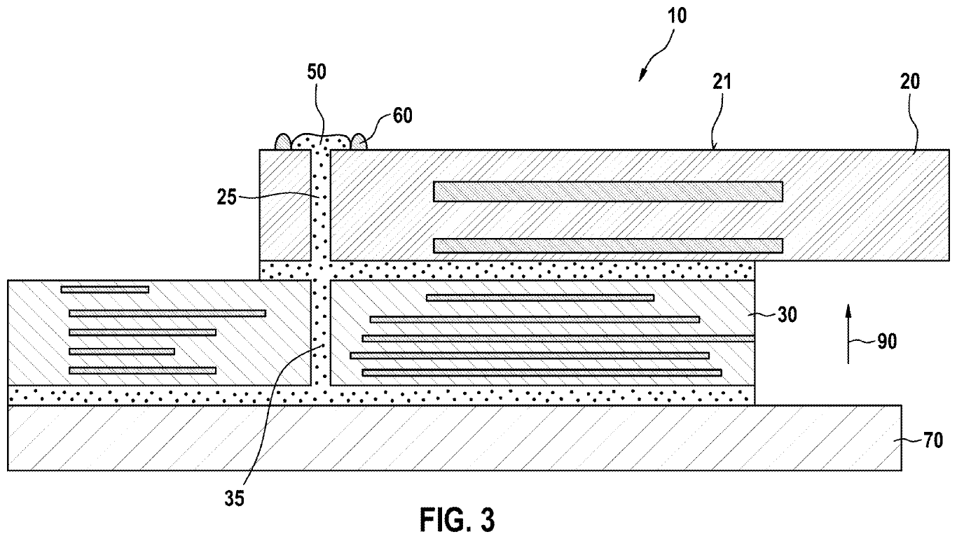

FIG. 3 shows a cross-sectional view of a third embodiment of the arrangement 10 according to the invention of electronic components 20, 30. In this case, the two electronic components 20, 30, or printed circuit board elements, are of equal width and are arranged above one another while being offset with respect to one another in the first direction 90. The first through-opening 25 has, in cross section perpendicularly to the first direction 90, the same diameter as the second through-opening 35 in cross section perpendicularly to the first direction 90. The first through-opening 25 is aligned flush with the second through-opening 35.

In the overlap region between the two printed circuit board elements, a part of the encapsulation compound 50 is arranged between the two printed circuit board elements. In addition, a part of the encapsulation compound 50 is arranged in the entire region between the second printed circuit board element and the heat sink 70.

Besides the dam material 60 on the first side 21 of the first printed circuit board element, FIG. 3 does not show any flow-limiting devices which prevent the fill material or encapsulation material from spreading or flowing further than as shown in FIG. 3.

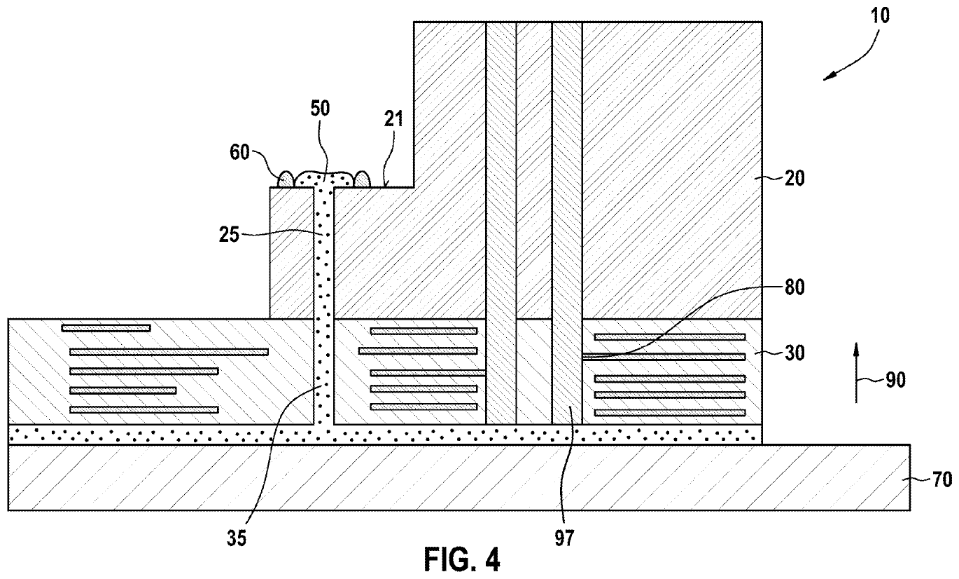

FIG. 4 shows a cross-sectional view of a fourth embodiment of the arrangement 10 according to the invention of electronic components 20, 30. The first electronic component 20 is in this case a sensor dome. The second electronic component 30 is a second printed circuit board element. The sensor dome comprises a solder pin 97, which is fitted into the second printed circuit board element. The solder pin 97 is electrically connected by means of a solder position 80, 81 to the second printed circuit board element (in this case a printed circuit board; PCB).

A part of the encapsulation compound 50 is arranged between the second printed circuit board element and the heat sink 70. A dam material 60 is applied around the inlet opening of the first through-opening 25 on a first side 21 of the sensor dome, which side faces away from the second printed circuit board element. The encapsulation compound 50, or the fill material, is subsequently applied onto that part of the first side 21 of the sensor dome which is enclosed by the dam material 60. The fill material flows through the first through-opening 25 into the second through-opening 35 and onto that side 21 of the second printed circuit board element which faces away from the sensor dome.

Besides the dam material 60 on the first side 21 of the first printed circuit board element, FIG. 4 does not show any flow-limiting devices which prevent the fill material or encapsulation material from spreading or flowing further than as shown in FIG. 4.

The sensor dome, or the electrical connections of the sensor dome, are electrically insulated by the encapsulation compound 50 below the second printed circuit board element from the heat sink 70.

Instead of a second through-opening 35, 36, in all embodiments presented the second electronic component 20, 30, or the second printed circuit board element, may comprise a blind hole which is open upward, or in the direction of the first electronic component 20, or of the first printed circuit board element, or of the first through-opening 25.

In conclusion, it should be pointed out that terms such as “having”, comprising”, etc. do not exclude other elements or steps, and terms such as “one” or “an” do not exclude a plurality. References in the claims are not to be regarded as restricting.

1. A method for mechanically connecting a first electronic component to a second electronic component comprising:
arranging and aligning, in a first direction, a first electronic component, which includes a first through-opening extending in the first direction, over a second electronic component, which includes one of a second through-opening and a blind hole extending in the first direction, in such a way that the one of the second through-opening and the blind hole is arranged at least partially below the first through-opening in the first direction;
introducing an encapsulation compound into the first through-opening and into the one of the second through-opening and the blind hole; and
curing the encapsulation compound in order to fix the first electronic component in relation to the second electronic component.

2. The method as claimed in claim 1, further comprising:
arranging the first electronic component above the second electronic component in the first direction in such a way the one of the second through-opening or and the blind hole is arranged fully below the first through-opening in the first direction, or in such a way that the first through-opening is arranged fully above the one of the second through-opening and the blind hole in the first direction.

3. The method as claimed in claim 1, wherein:
a first cross section of the first through-opening perpendicular to the first direction is elliptical or circular;
a second cross section of the one of the second through-opening and the blind hole perpendicular to the first direction is elliptical or circular; and
the arranging and aligning of the first electronic component includes aligning the first electronic component with respect to the second electronic component in such a way that the first through-opening is aligned coaxially with the one of the second through-opening and the blind hole.

4. The method as claimed in claim 1, further comprising:
electrically connecting the first electronic component to the second electronic component at a position located at most 0.75 mm away from at least one of the first through-opening and the one of the second through-opening and the blind hole.

5. The method as claimed in claim 1, further comprising:
applying a dam material, which extends around the first through-opening, onto a first side of the first electronic component, the first side facing away from the second electronic component ; and
applying a fill material as an encapsulation compound onto a first part of the first side of the first electronic component which is enclosed by the dam material in such a way that the fill material is introduced into the first through-opening and into the second through-opening or into the blind hole.

6. An arrangement of electronic components, comprising:
a first electronic component including a first through-opening extending in a first direction;
a second electronic component including one of a second through-opening and a blind hole extending in the first direction and arranged below the first electronic component in the first direction in such a way that the one of the second through-opening and the blind hole is arranged at least partially below the first through-opening in the first direction; and
a monobloc encapsulation compound connecting the first electronic component to the second electronic component, the encapsulation compound arranged in the first through-opening and in the second through-opening or the blind hole.

7. The arrangement as claimed in claim 6, wherein:
the one of the second through-opening and the blind hole is arranged fully below the first through-opening in the first direction; or
the first through-opening is arranged fully above the one of the second through-opening and the blind hole in the first direction.

8. The arrangement as claimed in claim 6, wherein a part of the encapsulation compound is arranged on a side of the second electronic component facing away from the first electronic component.

9. The arrangement as claimed in claim 6, wherein:
a first cross section of the first through-opening perpendicular to the first direction is elliptical or circular;
a second cross section of the one of the second through-opening and the blind hole perpendicular to the first direction is elliptical or circular; and
the first through-opening is aligned coaxially with the one of the second through-opening and the blind hole.

10. The arrangement as claimed in claim 6, wherein the encapsulation compound is arranged partially between the first electronic component and the second electronic component so as to form a surface connection between the first electronic component and the second electronic component.

11. The method as claimed in claim 1, wherein:
the first electronic component is a first printed circuit board element; and
the second electronic component is a second printed circuit board element.

12. The method as claimed in claim 4, wherein the position is located at most 0.55 mm away from at least one of the first through-opening and the one of the second through-opening and the blind hole.

13. The method as claimed in claim 6, wherein:
the first electronic component is a first printed circuit board element; and
the second electronic component is a second printed circuit board element.
